(19) United States
(12) Patent Application Publication
(10) Pub. No.: US 2026/0043136 A1
(43) Pub. Date: Feb. 12, 2026

(54) PROCESSING CHAMBER, SUBSTRATE PROCESSING METHOD, AND PROCESSING APPARATUS

(71) Applicant: Jiangsu Leadmicro Nano-Technology Co.,Ltd., WUXI (CN)

(72) Inventors: Shupeng SHI, WUXI (CN); Da YAN, WUXI (CN); Weimin LI, WUXI (CN); Xu KANG, WUXI (CN); Anlei SHEN, WUXI (CN)

(73) Assignee: Jiangsu Leadmicro Nano-Technology Co.,Ltd., WUXI (CN)

(21) Appl. No.: 19/365,220

(22) Filed: Oct. 22, 2025

Related U.S. Application Data
(63) Continuation of application No. PCT/CN2024/085480, filed on Apr. 2, 2024.

(30) Foreign Application Priority Data
Apr. 23, 2023 (CN) 202310437556.6

(51) Int. Cl. C23C 16/455; C23C 16/40; C23C 16/44

(52) U.S. Cl. CPC C23C 16/45544; C23C 16/403; C23C 16/4412

(57) ABSTRACT

A processing chamber includes a chamber body assembly and a chamber door assembly. The chamber body assembly includes a chamber body. The chamber door assembly includes a spray plate and a chamber door. The spray plate is disposed on the chamber door. When the chamber door assembly is closed, the spray plate covers an end of the chamber body. The chamber body and the spray plate define a processing space. The spray plate is configured to introduce a processing gas into the processing space. A substrate processing method and a processing device are further provided.

### CROSS-REFERENCE TO RELATED APPLICATIONS

The present application is a continuation of International Patent Application No. PCT/CN2024/085480, filed on Apr. 2, 2024, which claims priority to Chinese Patent Application No. 202310437556.6, filed on Apr. 23, 2023, both of which are herein incorporated by reference in their entirety.

### TECHNICAL FIELD

The present disclosure relates to the technical field of substrate processing, and in particular to a processing chamber, a substrate processing method, and a processing device.

### BACKGROUND

Many substrate processing processes require participation of gas. Controlling a flow rate of the gas, a flow field of the gas, and the like are important focuses in gas-involved processing processes. In addition, for processing devices, achieving the same or better effect with fewer components is also a consistent research focus for device manufacturers.

For example, in the field of chemical vapor deposition, from the perspective of production capacity, it is necessary to process a large number of substrates simultaneously in the industry. Controlling uniformity and stability of a gas flow is key to ensuring uniformity of the substrate processing. Moreover, in an atomic layer deposition method, different gases need to be introduced, and requirements for gas control are even higher. Processing chambers in the related art configured for atomic layer deposition mostly adopt a double-layer chamber structure, including an outer chamber body and an inner chamber body. The inner chamber body is accommodated in the outer chamber body, and a heating system is disposed between the outer chamber body and the inner chamber body. One end of the inner chamber body is connected to an inlet pipe, and an opposite end of the inner chamber body is connected to a vacuum pump. The inlet pipe is configured to introduce processing gas into the inner chamber body, while the outer chamber body is filled with an inert gas. The vacuum pump can simultaneously evacuate both the inner chamber body and the outer chamber body and control a flow direction of the processing gas in the inner chamber body. By controlling the amount of the processing gas, one or more atomic layers can be deposited. With development of a substrate technology and increasing size of a substrate, the inner chamber body of this double-layer chamber structure is difficult to meet production requirements of large-sized substrate due to its limited storage space. Expanding a volume of the inner chamber body will inevitably lead to the outer chamber body occupying more space, resulting in complex structure, large volume, and high costs of the processing chamber. In addition, using the inlet pipe for gas supply makes it difficult to form a uniform and stable gas flow in the processing chamber, resulting in poor uniformity of the substrate processing. Therefore, providing a processing chamber with a simple structure, a small volume, low costs, and the uniform and stable gas flow has become an urgent technical problem to be solved.

### SUMMARY OF THE DISCLOSURE

The present disclosure provides a processing chamber. The processing chamber includes a chamber body assembly including a chamber body and a chamber door assembly including a spray plate and a chamber door. The spray plate is disposed on the chamber door. When the chamber door assembly is closed, the spray plate is disposed on and covers an end of the chamber body. The chamber body and the spray plate enclose or define a processing space, and the spray plate is configured to introduce a processing gas into the processing space.

The present disclosure provides a substrate processing method, including:
transferring the carrier that is configured to load a substrate into the above processing chamber; and
covering the spray plate on the chamber body, and introducing the processing gas into the processing space through the spray plate to process the substrate.

The present disclosure provides a processing device including at least two above processing chambers. The at least two processing chambers are stacked and connected in a horizontal direction or a vertical direction. A side wall of a connection area between every two adjacent processing chambers defines an opening, so that the at least two processing chambers are communicated. The processing chamber includes the chamber body, the chamber body is configured to accommodate the carrier, and the carrier is configured for loading the substrate. A heater is disposed between the carrier and the inner side wall of the chamber body, and the heater is distributed around the chamber body. An end of the chamber body is provided with the spray plate, and a gas outlet part of the spray plate corresponds to the cross-section of the carrier. The spray plate and the chamber body enclose or define the processing space, and the spray plate is configured to introduce the processing gas into the processing space to process the substrate.

### BRIEF DESCRIPTION OF THE DRAWINGS

In order to more clearly describe the technical solutions in some embodiments of the present disclosure, hereinafter, the accompanying drawings that are used in the description of some embodiments will be briefly described. Obviously, the accompanying drawings in the description below merely show some embodiments of the present disclosure. For those of ordinary skill in the art, other accompanying drawings may be obtained based on these accompanying drawings without any creative efforts.

FIG. 1 is a structural schematic view of an embodiment of a processing chamber provided in the present disclosure.

FIG. 2 is a cross-sectional structural schematic view from a perspective along a longitudinal direction of an embodiment of the processing chamber provided in the present disclosure.

FIG. 3 is a structural schematic view of an embodiment of a heater provided in the present disclosure.

FIG. 4 is a structural schematic view of an embodiment of a gas-extracting cylinder provided in the present disclosure.

FIG. 5 is a schematic view illustrating a gas introduction mode of the processing chamber in the embodiment of FIG. 2.

FIG. 6 is a cross-sectional structural schematic view from a perspective along a longitudinal direction of another embodiment of the processing chamber provided in the present disclosure.

FIG. 7 is a schematic view illustrating a gas introduction mode of the processing chamber in the embodiment of FIG. 6.

FIG. 8 is a structural schematic view from a perspective of an embodiment of a chamber door opening and closing mechanism provided in the present disclosure.

FIG. 9 is a structural schematic view from another perspective of an embodiment of the chamber door opening and closing mechanism provided in the present disclosure.

FIG. 10 is a flowchart of an embodiment of a substrate processing method provided in the present disclosure.

FIG. 11 is a structural schematic view of an embodiment of a processing device provided in the present disclosure.

FIG. 12 is a structural schematic view of another embodiment of the processing device provided in the present disclosure.

### DETAILED DESCRIPTION

The present disclosure may be explained in detail by combining the accompanying drawings and embodiments. It should be noted that the following embodiments are only used to illustrate the present disclosure, but do not limit the scope of the present disclosure. Similarly, the following embodiments are only a part of the embodiments of the present disclosure, and not all embodiments. All other embodiments obtained by those of ordinary skill in the art without creative effort are within the scope of the present disclosure.

In the description of the present disclosure, “multiple” or “plurality” means at least two, such as two, three, etc., unless otherwise expressly and specifically qualified. The terms “first”, “second”, and “third” in the present disclosure are only configured to describe and cannot be understood as indicating or implying relative importance or implicitly indicating the quantity of technical features indicated. Therefore, features that are defined as “first”, “second”, and “third” may explicitly or implicitly include at least one of these features. All directional indications (such as up, down, left, right, front, rear, or the like) in some embodiments of the present disclosure are only configured to explain a relative position relationship between components in a specific posture (as shown in the accompanying drawings), a motion situation between the components in the specific posture (as shown in the accompanying drawings), or the like. When the specific posture is changed, the directional indication is also changed accordingly. In addition, the terms “including”, “comprising”, and “having”, as well as any variations of the terms “including”, “comprising”, and “having” in some embodiments of the present disclosure, are intended to cover non-exclusive inclusions. For example, a process, method, system, product, or device that includes a series of operations or units is not limited to the listed operations or units, but optionally includes operations or units that are not listed, or optionally includes other operations or units that are inherent to these processes, methods, products, or devices.

The reference to “embodiment” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure can be combined with other embodiments.

The present disclosure provides a processing chamber, a substrate processing method, and a processing device that can solve problems of complex structure of the processing chamber, large volume of the processing chamber, high costs of the processing chamber, and poor stability of gas flow uniformity in the processing chamber.

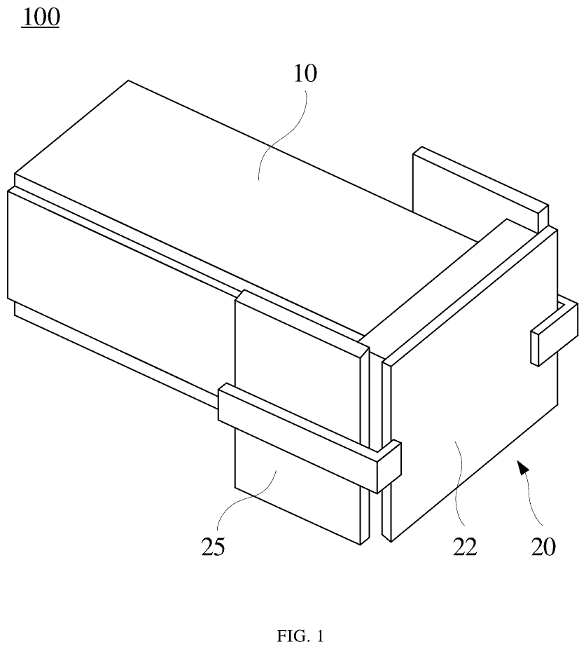

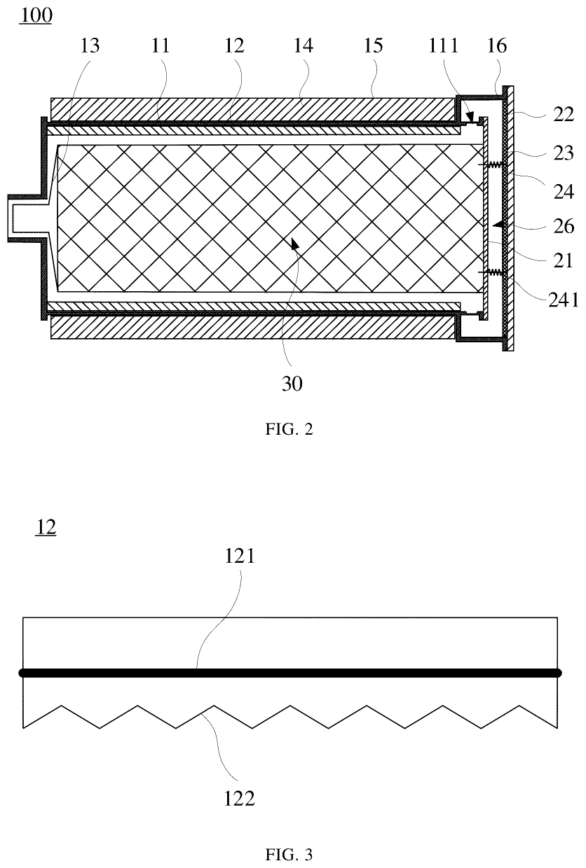

The present disclosure provides a processing chamber. As illustrated in FIGS. 1 and 2, the processing chamber 100 may include a chamber body assembly 10 and a chamber door assembly 20. The chamber body assembly 10 and the chamber door assembly 20 enclose or define a processing space 30.

In some embodiments, the chamber body assembly 10 includes a chamber body 11, and the chamber door assembly 20 includes a spray plate 21 and a chamber door 22. The spray plate 21 is disposed on the chamber door 22. When the chamber door assembly 20 is closed, the spray plate 21 is disposed on and covers an end of the chamber body 11. The chamber body 11 and the spray plate 21 enclose or define the processing space 30, and the spray plate 21 is configured to introduce a processing gas into the processing space 30. The processing chamber 100 is configured to accommodate a carrier that is configured to load a substrate, and the carrier is located in the processing space 30. The spray plate 21 is disposed on and covers the chamber body 11, and the processing gas is introduced into the processing space 30 through the spray plate 21 to process the substrate. The above mentioned “disposed on and covers” is designed to achieve a tight fit between the spray plate 21 and the chamber body 11. This may be accomplished by using an elastic mechanism to provide a pressing force or clamping force, thereby minimizing a gap between the spray plate 21 and the chamber body 11. A contact part between the spray plate 21 and the chamber body 11 may be in direct contact or attached using a sealing medium.

The chamber body 11 includes a main structure. The main structure may be made of a metal material, as well as corresponding auxiliary structure such as a reinforcing rib. A matching component or a matching structure may also be disposed on the main structure. In some embodiments, a hole is defined in the main structure, and the hole is configured for allowing an electrode to insert or extracting the gas. In some embodiments, when it is necessary to extract the gas from the chamber body 11, gas-tight structures need to be disposed at corresponding positions. These components or structures are disposed according to needs, and addition of these components or structures does not affect definition of the chamber body 11 in the present disclosure.

The chamber body 11 is roughly shaped as a cube or a cylinder in space. Based on the above shape, a surface is opened, and a corresponding spray plate 21 is disposed on the opened surface, thereby forming the processing space 30 together with the spray plate 21. The processing space 30 may roughly be a cube space or a cylindrical space.

The types of the processing gases may be introduced according to actual needs. When a Al₂O₃ film needs to be deposited, the processing gases may be water vapor and trimethylaluminum (TMA). The processing gases are not limited to these two, and the above is only an illustrative example. When the substrate is in contact with multiple processing gases, chemical vapor phase reactions occur between the multiple processing gases, and atomic layers are deposited on the substrate in a layer-by-layer manner.

The processing chamber 100 provided in the present disclosure simplifies the processing chamber 100 and its internal structure by integrating a traditional double-layer chamber body into a single-layer chamber body 11, with the spray plate 21 covering the chamber body 11. This increases an internal space of the chamber body 11 when the processing chamber 100 occupies the same usage space. The chamber body 11 can accommodate larger and more substrates, thereby improving processing capacity and reducing production costs. Since the spray plate 21 is configured to introduce the processing gas into the processing space 30, the gas flow in the processing space 30 is more uniform and stable, which can improve the uniformity of the substrate processing.

The chamber body 11 is a single-layer, which means that the main structure forming the chamber body 11 has only one layer. The main structure may include other sub-layers that achieve the chamber body function. The one layer may include the sub-layers, such as an insulation layer, a cooling layer, an outer shell layer, etc. When integrating a heating function, it may also include a heating layer.

The substrate and the carrier that accommodates or supports the substrate are usually rectangular. In order to match a shape of the carrier, in some embodiments, the chamber body 11 has two parallel chamber walls, and a corresponding number of substrates may be set according to needs. In some embodiments, a cross-section of the chamber body 11 in a vertical direction is rectangular, and more substrates can be loaded through shape selection and arrangement.

In some embodiments, the chamber body assembly 10 further includes a heater 12, a gas-extracting cylinder 13, and an insulation layer 14.

The heater 12 is disposed on four surfaces of an inner side wall of the chamber body 11. The heater 12 includes a heating element 121 and a heating cover 122, and the heating element 121 is accommodated in the heating cover 122, as shown in FIG. 3. A surface of the heating cover 122 is disposed on the inner side wall of the chamber body 11, and an opposite surface of the heating cover 122 is corrugated. Due to the single-layer structure of the chamber body 11, the heater 12 can directly heat the processing gas. Compared with the double-layer chamber structure where a heating system is located between an outer chamber body and an inner chamber body, the processing chamber 100 provided in the present disclosure has higher heating efficiency, faster gas temperature rise, which can effectively shorten the preheating time and improve the processing efficiency.

In some embodiments, the heater 12 may be detachably connected to the inner side wall of the chamber body 11. An installation mode of the heater 12 may be plug-in, snap-fit, or the like. An auxiliary mobile device such as a limit rail may also be disposed simultaneously. The detachable connection mode and the auxiliary mobile device are used simultaneously, so as to facilitate disassembly, replacement, and maintenance of the heater 12. A surface of the heater 12 is coated with a material that is not affected by the corresponding processing in the processing space 30. For example, during film deposition, the material of the coating does not react with a precursor or a reactive gas under processing conditions. By disposing the coating, the heater 12 located in the processing space 30 can be prevented from being processed during the substrate processing.

The gas-extracting cylinder 13 is connected to an end of the chamber body 11 away from the spray plate 21. A cross-section of the gas-extracting cylinder 13 tapers in a direction away from the spray plate 21. The processing gas is drawn out through the gas-extracting cylinder 13. The tapered design stabilizes the gas flow field in the processing space 30 during evacuation, allowing the substrate accommodated in the chamber body 11 to make full contact with the processing gas, thereby improving the processing efficiency.

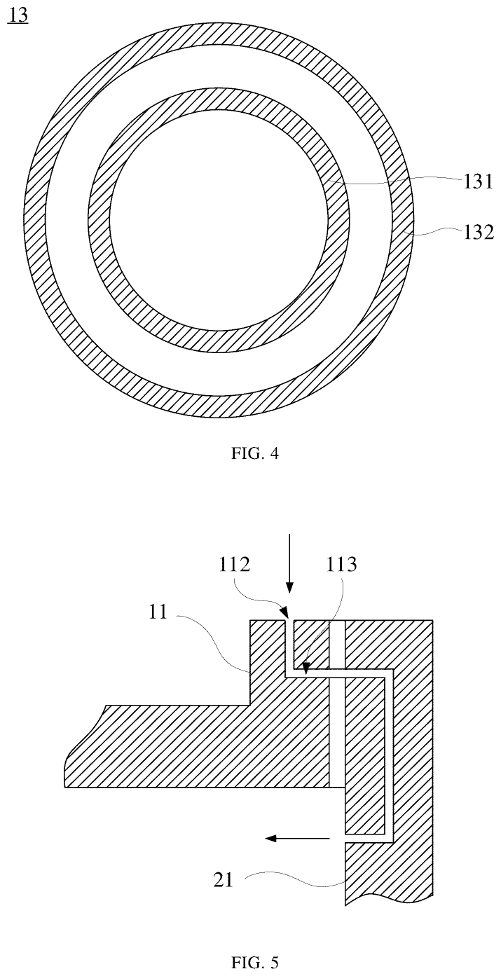

In some embodiments, the gas-extracting cylinder 13 includes an inner ring gas-extracting cylinder 131 and an outer ring gas-extracting cylinder 132, as shown in FIG. 4. The outer ring gas-extracting cylinder 132 is sleeved outside the inner ring gas-extracting cylinder 131. The inner ring gas-extracting cylinder 131 may be in direct contact with the carrier, so as to extract the processing gas inside the carrier. The outer ring gas-extracting cylinder 132 is configured to extract the gas from a space between the carrier and the chamber body 11. By disposing the inner ring gas-extracting cylinder 131 and the outer ring gas-extracting cylinder 132, an inner and outer double ring gas-extracting structure is formed, the gas inside and outside of the carrier can independently be extracted, thereby forming the uniform and stable gas flow inside and outside the carrier, and improving the uniformity of the substrate processing.

As illustrated in FIG. 2, the insulation layer 14 surrounds the periphery of the chamber body 11, and a protective cover 15 surrounds the insulation layer 14. A grounding wire is disposed on the protective cover 15. Disposing the insulation layer 14 can reduce diffusion of heat in the processing space 30 and maintain a stable gas temperature inside the processing space 30. The protective cover 15 can prevent burns from a high temperature, and the grounding wire disposed on the protective cover 15 can avoid the risk of electric shock.

In some embodiments, the chamber door assembly 20 further includes a thermal insulation layer 23, support columns 24, and a chamber door opening and closing mechanism 25. Multiple support columns 24 are connected to an inner side wall of the chamber door 22, and the spray plate 21 is slidably disposed on the support columns 24. When the chamber door assembly 20 is closed, the spray plate 21 is tightly pressed against the chamber body 11. The spray plate 21, the chamber door 22, and the chamber body 11 enclose or define a chamber door space 26. The chamber door space 26 is filled with a barrier gas, and the barrier gas does not undergo chemical gas phase reaction with the processing gas. The barrier gas may be an inert gas or nitrogen gas. Gas pressure inside the chamber door space 26 is greater than that inside the processing space 30, which can prevent the processing gas from leaking out from a contact area between the spray plate 21 and the chamber body 11. In conjunction with the gas-extracting cylinder 13, the processing gas sprayed from the spray plate 21 can stably flow towards one end of the gas-extracting cylinder 13, thereby forming the uniform and stable flow field of the processing gas in the chamber body 11. Therefore, the substrate accommodated in the chamber body 11 can fully contact with the processing gas, thereby improving the uniformity of the substrate processing.

The thermal insulation layer 23 is in direct contact with the inner side wall of the chamber door 22. The thermal insulation layer 23 can prevent heat exchange between the gas inside the chamber body 11 and the outside of the chamber body 11, thereby ensuring a relatively constant temperature for substrate processing inside the chamber body 11.

Each support column 24 is provided with a support spring 241. When the chamber door assembly 20 is closed, the support spring 241 presses the spray plate 21 tightly against the chamber body 11, which can improve airtightness of the contact area between the spray plate 21 and the chamber body 11, thereby preventing the processing gas from leaking out of the processing space 30.

A position where the chamber body 11 is in contact with the spray plate 21 usually has a surface-to-surface contact, and this contact surface may be specially treated, such as reducing surface roughness and improving flatness to achieve a tight fit between the two surfaces. When supplying the gas, it is not desired for the gas to leak out from gaps of the contact area. By disposing the chamber door space 26 and the support spring 241, it can prevent the gas from leaking out of the processing space 30. In order to further prevent the processing gas from leaking out of the processing space 30, in some embodiments, multiple gas curtain holes 111 are defined in the inner side wall of the chamber body 11, as shown in FIG. 2. The gas curtain holes 111 are defined close to the contact area of the spray plate 21 and the chamber body 11, and multiple gas curtain holes 111 are distributed at intervals around inner circumference of the chamber body 11. The gas curtain holes 111 can introduce the barrier gas into the processing space 30, and the barrier gas forms an isolation gas curtain at the contact area between the chamber body 11 and the spray plate 21, which can further prevent the processing gas from leaking out from the contact area between the spray plate 21 and the chamber body 11.

As illustrated in FIG. 2, in some embodiments, the chamber body 11 is provided with an outer sleeve 16, and a cross-sectional area of the outer sleeve 16 is greater than that of the chamber body 11. The outer sleeve 16 is connected to an outer side wall of the chamber body 11. An end of the chamber body 11 that is in contact with the spray plate 21 may be flush with a connection position between the outer sleeve 16 and the chamber body 11. Alternatively, the end of the chamber body 11 that is in contact with the spray plate 21 can also partially extend into the outer sleeve 16. When the chamber door assembly 20 is closed, the spray plate 21 is attached to or is in contact with the chamber body 11, and the chamber door 22 is in contact with the outer sleeve 16, to form the chamber door space 26. The contact area may be in direct contact or tightly attached using the sealing medium.

A gas source interface 112 is defined on the chamber body 11. The gas source interface 112 may be located or defined within the range of the outer sleeve 16 or outside the range of the outer sleeve 16. As illustrated in FIG. 5, FIG. 5 is a schematic view illustrating a gas introduction mode of the processing chamber 100 in the embodiment of FIG. 2. Multiple gas inlet channels 113 are defined at the contact area between the chamber body 11 and the spray plate 21. Gas outlets of the multiple gas inlet channels 113 correspond to a gas inlet of the spray plate 21. When the spray plate 21 is in contact with the chamber body 11, an external gas source can enter the processing space 30 through the gas source interface 112, the gas inlet channel 113, and the spray plate 21. The gas source interface 112 is defined on the chamber body 11, and the chamber body 11 does not move with the opening and closing of the spray plate 21. Therefore, the opening and closing of the spray plate 21 cannot affect the gas source pipeline, so that the gas source pipeline may be relatively fixed.

The multiple gas inlet channels 113 may be independent of each other. In some embodiments, when the processing chamber 100 is used for the atomic layer deposition (ALD), different precursor or reactant gases enter the spray plate 21 through different gas inlet channels 113. The gas paths in the spray plate 21 may also be set as independent gas paths, and different gases are redistributed through different gas paths before entering the chamber body 11.

Relatively speaking, when the end of the chamber body 11 that is in contact with the spray plate 21 is flush with the connection position between the outer sleeve 16 and the chamber body 11, the gas source pipeline can be more conveniently connected to the chamber body 11, which is beneficial for design and manufacturing of the gas paths.

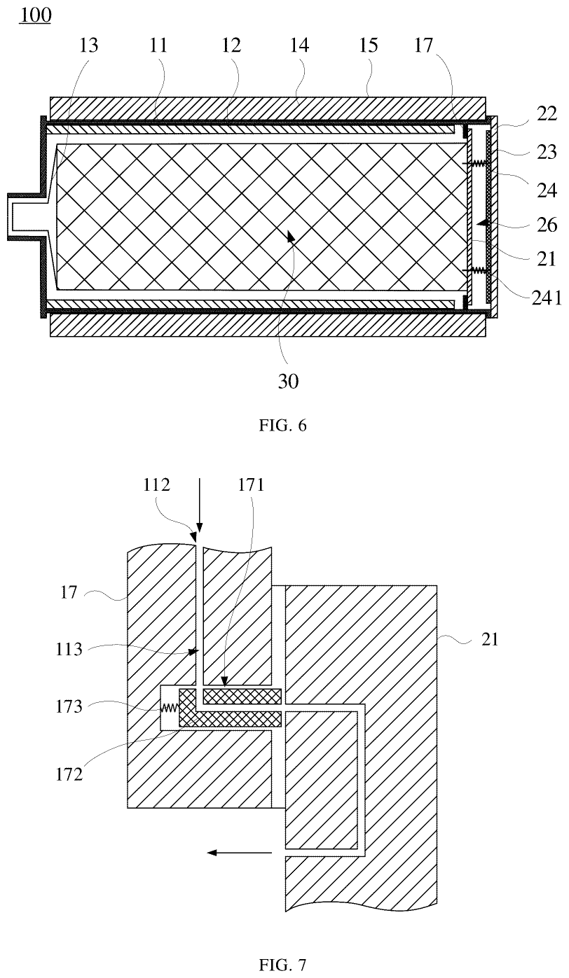

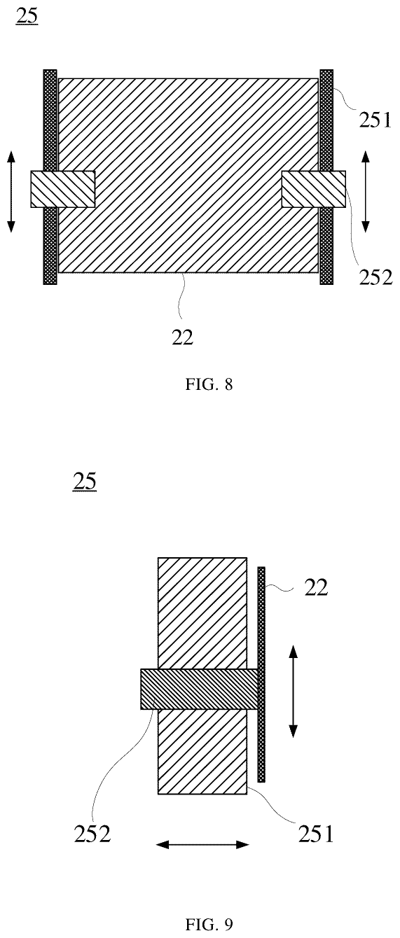

The processing chamber 100 may also adopt other gas inlet modes, as illustrated in FIG. 6 and FIG. 7. In some embodiments, an inner side wall of the end of the chamber body 11 that is in contact with the spray plate 21 is provided with an annular flange 17. When the chamber door assembly 20 is closed, the spray plate 21 is in contact with the annular flange 17, and the chamber door 22 is in contact with the chamber body 11, to form the chamber door space 26. In some embodiments, multiple installation holes 171 are defined at the contact area between the annular flange 17 and the spray plate 21. Each installation hole 171 accommodates a gas guide member 172, and both the annular flange 17 and the gas guide member 172 define the gas inlet channel 113. The gas outlet of the gas inlet channel 113 corresponds to the gas inlet of the spray plate 21. The chamber body 11 defines the gas source interface 112. When the spray plate 21 is in contact with the annular flange 17, the external gas source can enter the processing space 30 through the gas source interface 112, the gas guide member 172, and the spray plate 21. Due to the annular flange 17 being located on the inner side wall of the chamber body 11, a cross-section of the processing chamber 100 remains unchanged, which can further simplify the chamber structure of the processing chamber 100 and reducing costs.

In some embodiments, a retractable spring 173 is disposed inside the installation hole 171, and an end of the gas guide member 172 is connected to the annular flange 17 through the retractable spring 173. When the spray plate 21 is in contact with the annular flange 17, the spray plate 21 compresses the retractable spring 173, and the retractable spring 173 generates a thrust, so that an opposite end of the gas guide member 172 is tightly pressed against the spray plate 21. By disposing the retractable spring 173, the gas guide member 172 can be tightly attached to the spray plate 21. Even if there are certain processing or assembly errors at a contact area between the spray plate 21 and the annular flange 17, a well-sealed gas flow channel can still be formed.

In some embodiments, the gas guide member 172 and the retractable spring 173 may also be disposed in the embodiment of FIG. 5, thereby improving the airtightness of gas conduction between the spray plate 21 and the chamber body 11, and reducing the risk of gas leakage.

As illustrated in FIG. 1, FIG. 8, and FIG. 9, the chamber door opening and closing mechanism 25 is respectively connected to the chamber body 11 and the chamber door 22. The chamber door opening and closing mechanism 25 is configured for opening or closing the chamber door assembly 20. The chamber door opening and closing mechanism 25 includes first chamber door opening and closing mechanisms 251 and second chamber door opening and closing mechanisms 252. Each of two opposite sides of the chamber door 22 is provided with the first chamber door opening and closing mechanism 251. The first chamber door opening and closing mechanism 251 is respectively connected to the chamber door 22 and the chamber body 11. The first chamber door opening and closing mechanism 251 drives the chamber door 22 and the spray plate 21 to move in a first direction, so that the chamber door 22 and the spray plate 21 cover the chamber body 11.

The second chamber door opening and closing mechanism 252 is connected to the first chamber door opening and closing mechanism 251. The second chamber door opening and closing mechanism 252 drives the chamber door 22 and the spray plate 21 to move in a second direction, so that the chamber door 22 and the spray plate 21 cover the chamber body 11. The second direction is perpendicular to the first direction. In some embodiments, the first direction may be a vertical direction, and the second direction may be a longitudinal direction of the processing chamber 100. The first chamber door opening and closing mechanism 251 and the second chamber door opening and closing mechanism 252 allow the chamber door 22 and the spray plate 21 to translate in two directions, so that the chamber door assembly 20 is opened or closed.

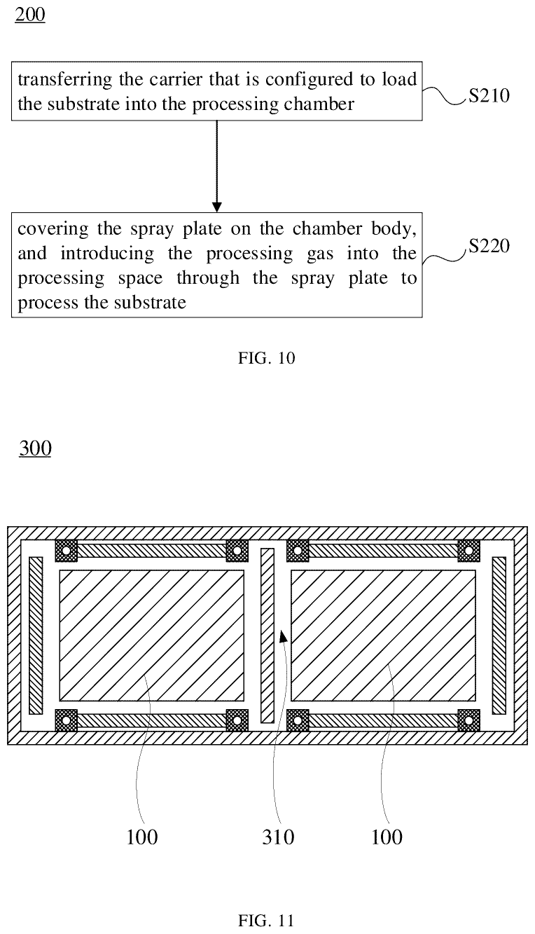

The present disclosure provides a substrate processing method, and the substrate processing method 200 may include an operation at block S210 and an operation at block S220. As illustrated in FIG. 10, FIG. 10 is a flowchart of an embodiment of the substrate processing method provided in the present disclosure.

At block S210, the substrate processing method may include transferring the carrier that is configured to load the substrate into the processing chamber 100.

At block S220, the substrate processing method may include covering the spray plate 21 on the chamber body 11, and introducing the processing gas into the processing space 30 through the spray plate 21 to process the substrate.

The processing may require the participation of the gas. The role of the gas may be introducing doping elements, film growth, protecting the surface, etc. The specific processing may be doping, coating, protective annealing, etc. The following description provides a detailed explanation, taking the coating process as an example.

The substrate is placed into the carrier, and then the carrier is placed into the processing chamber 100. The gas is introduced into the spray plate 21, and the gas can grow a thin film on a surface of the substrate. By controlling parameters such as type of the gas, the temperature, etc., the desired thin film layer can be grown.

The material of the carrier may be selected according to the requirements of the processing. In some embodiments, during the ALD processing, due to the relatively low temperature, the metal material such as aluminum may be selected.

The carrier may be of an enclosable type, such as a relatively independent box-like type. An elastic mechanism is disposed between the gas-extracting cylinder 13 and the chamber body 11. After the carrier loads the substrate, the end of the carrier is in contact with the spray plate 21, and the opposite end of the carrier is in contact with the inner ring gas-extracting cylinder 131, thereby forming a relatively independent gas flow space from the spray plate 21 to the carrier, and making the gas flow inside the carrier more uniform and stable.

The spray plate 21 introduces the processing gas into the carrier. In order to maintain a relatively stable gas flow in the carrier and prevent it from flowing into the space between the carrier and the chamber body 11, the barrier gas is introduced into the processing space 30 outside the carrier through the gas curtain holes 111. The pressure of the barrier gas is greater than that of the processing gas, so that the processing gas does not flow out of the carrier.

The enclosable carrier may also be matched with the inner and outer double ring gas-exhausting structure. The inner ring gas-extracting cylinder 131 extracts the processing gas inside the carrier, and the outer ring gas-extracting cylinder 132 extracts the barrier gas between the carrier and the chamber body 11. Therefore, a uniform and stable gas flow inside and outside the carrier is formed, which can improve the uniformity of the substrate processing.

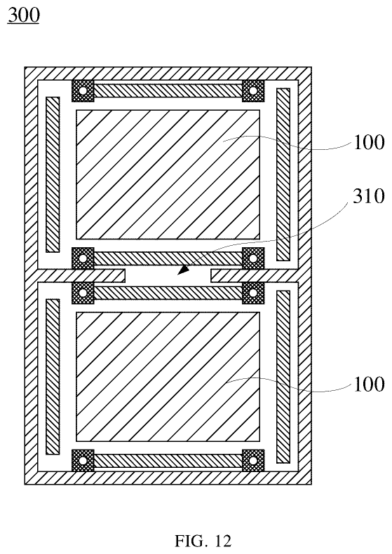

The present disclosure provides a processing device, as shown in FIGS. 11 and 12. The processing device 300 includes at least two processing chambers 100 as described above, and the at least two processing chambers 100 are stacked and connected in a horizontal direction or a vertical direction. A side wall of a connection area between every two adjacent processing chambers 100 defines an opening 310, so that the at least two processing chambers 100 are communicated. The number of the opening 310 may be one or multiple. The opening 310 may also cover the entire connection side wall, merging the two adjacent processing chambers 100 into one. The processing chamber 100 includes the chamber body 11. The chamber body 11 is configured to accommodate the carrier, and the carrier is configured for loading the substrate. The heater 12 is disposed between the carrier and the inner side wall of the chamber body 11, and the heater 12 is distributed around the chamber body 11. An end of the chamber body 11 is provided with the spray plate 21, and a gas outlet part of the spray plate 21 corresponds to the cross-section of the carrier. The spray plate 21 and the chamber body 11 enclose or define the processing space 30, and the spray plate 21 is configured to introduce the processing gas into the processing space 30 to process the substrate. At least two processing chambers 100 are communicated to form the processing device 300. The processing device 300 may share a single heater 12 at the connection area, thereby reducing the number of the heaters 12. Multiple processing chambers 100 may share a single gas source, reducing the number of the gas sources, thereby reducing the processing costs. The processing device 300 has a more compact overall structure compared with multiple dispersed and separately arranged processing chambers 100, which can reduce a volume of a machine that accommodates the processing chambers 100.

The processing chamber 100 provided in the present disclosure has at least the following effects.

First, by integrating the traditional double-layer chamber body into the single-layer chamber body 11, with the spray plate 21 covering the chamber body 11, the processing chamber 100 and its internal structure are simplified. Therefore, the chamber body 11 can accommodate larger and more substrates, thereby improving processing capacity and reducing production costs. Since the spray plate 21 is configured to introduce the processing gas into the processing space 30, the gas flow in the processing space 30 is more uniform and stable, which can improve the uniformity of the substrate processing.

Second, the cross-section of the chamber body 11 is rectangular, which can match with the shape of the carrier that accommodates the substrate. Therefore, the chamber body 11 having the rectangular cross-section can accommodate more substrates.

Third, the gas-extracting cylinder 13 includes the inner ring gas-extracting cylinder 131 and the outer ring gas-extracting cylinder 132, which can respectively perform relatively independent gas-extracting on the inside and outside the carrier, thereby forming the uniform and stable gas flow inside and outside the carrier, and improving the uniformity of the substrate processing.

Fourth, the spray plate 21, the chamber door 22, and the chamber body 11 enclose or define the chamber door space 26. The gas pressure in the chamber door space 26 is greater than that in the processing space 30, which can prevent the leakage of the processing gas and form the uniform and stable flow field in the chamber body 11, thereby improving the uniformity of the substrate processing.

Fifth, the support column 24 is sleeved with the support spring 241, and the support spring 241 presses the spray plate 21 tightly against the chamber body 11, which can improve the airtightness of the contact area between the spray plate 21 and the chamber body 11, thereby preventing the processing gas from leaking out of the processing space 30.

Sixth, the inner side wall of the chamber body 11 defines multiple gas curtain holes 111. The gas curtain holes 111 can introduce the barrier gas into the processing space 30, and the barrier gas forms the isolation gas curtain at the contact area between the chamber body 11 and the spray plate 21, which can further prevent the processing gas from leaking out from the contact area between the spray plate 21 and the chamber body 11.

Seventh, the gas source interface 112 is defined on the chamber body 11, and the chamber body 11 does not move with the opening and closing of the spray plate 21. Therefore, the opening and closing of the spray plate 21 cannot affect the gas source pipeline, so that the gas source pipeline may be relatively fixed.

Eighth, by disposing the annular flange 17 on the inner side wall of the chamber body 11, the cross-section of the processing chamber 100 remains unchanged, which can further simplify the chamber structure of the processing chamber 100.

Ninth, the contact area between the spray plate 21 and the chamber body 11 is provided with the gas guide member 172 and the retractable spring 173, which can improve the airtightness of the gas conduction between the spray plate 21 and the chamber body 11, and reducing the risk of the gas leakage.

Tenth, the processing device 300 has the more compact overall structure compared with multiple dispersed and separately arranged processing chambers 100, which can reduce the volume of the machine that accommodates the processing chambers 100. The processing device 300 can also reduce the number of the heaters 12 and the gas sources, thereby reducing the processing costs.

The above descriptions are only some embodiments of the present disclosure, and are not intended to limit the protection scope of the present disclosure. Any equivalent device or equivalent flow transformation made by using the contents and the accompanying drawings of the present disclosure, or directly or indirectly applied to other related technical fields, is included in the protection scope of the present disclosure.

1. A processing chamber, comprising:
a chamber body assembly, comprising a chamber body; and
a chamber door assembly, comprising a spray plate and a chamber door; wherein the spray plate is disposed on the chamber door; when the chamber door assembly is closed, the spray plate is disposed on and covers an end of the chamber body; the chamber body and the spray plate define a processing space, and the spray plate is configured to introduce a processing gas into the processing space.

2. The processing chamber as claimed in claim 1, wherein the chamber body is a single layer.

3. The processing chamber as claimed in claim 1, wherein the chamber body comprises two chamber walls parallel to each other.

4. The processing chamber as claimed in claim 3, wherein a cross-section of the chamber body in a vertical direction is rectangular.

5. The processing chamber as claimed in claim 1, wherein the chamber door assembly comprises a plurality of support columns, the plurality of support columns are connected to an inner side wall of the chamber door, and the spray plate is slidably disposed on the plurality of support columns;
when the chamber door assembly is closed, the spray plate is attached to the chamber body, so that the spray plate, the chamber door, and the chamber body define a chamber door space; and gas pressure in the chamber door space is greater than that in the processing space.

6. The processing chamber as claimed in claim 5, wherein the chamber door assembly comprises a thermal insulation layer, and the thermal insulation layer is in contact with the inner side wall of the chamber door.

7. The processing chamber as claimed in claim 5, wherein a support spring is sleeved on each support column; and when the chamber door assembly is closed, the support spring presses the spray plate against the chamber body.

8. The processing chamber as claimed in claim 5, wherein a plurality of gas curtain holes are defined on an inner side wall of the chamber body, the plurality of gas curtain holes are defined close to a contact area between the chamber body and the spray plate, and the plurality of gas curtain holes are distributed at intervals around inner circumference of the chamber body; and the plurality of gas curtain holes are configured to introduce a barrier gas into the processing space, and the barrier gas is able to form an isolation gas curtain at the contact area between the chamber body and the spray plate.

9. The processing chamber as claimed in claim 5, wherein the chamber body is provided with an outer sleeve, and a cross-sectional area of the outer sleeve is greater than that of the chamber body; the outer sleeve is connected to an outer side wall of the chamber body; an end of the chamber body that is in contact with the spray plate is flush with a connection position between the outer sleeve and the chamber body, or the end of the chamber body that is in contact with the spray plate partially extends into the outer sleeve;
when the chamber door assembly is closed, the spray plate is in contact with the chamber body, and the chamber door is in contact with the outer sleeve, to form the chamber door space.

10. The processing chamber as claimed in claim 9, wherein a gas source interface is defined on the chamber body; a plurality of gas inlet channels are defined at a contact area between the chamber body and the spray plate, and gas outlets of the plurality of gas inlet channels correspond to gas inlets of the spray plate; and when the spray plate is in contact with the chamber body, an external gas source is able to enter the processing space through the gas source interface, the plurality of gas inlet channels, and the spray plate.

11. The processing chamber as claimed in claim 5, wherein an inner side wall of an end of the chamber body that is in contact with the spray plate is provided with an annular flange;
when the chamber door assembly is closed, the spray plate is in contact with the annular flange, and the chamber door is in contact with the chamber body, to form the chamber door space.

12. The processing chamber as claimed in claim 11, wherein a plurality of installation holes are defined at a contact area between the annular flange and the spray plate, each installation hole accommodates a gas guide member, and both the annular flange and the gas guide member define a gas inlet channel; a gas outlet of the gas inlet channel corresponds to a gas inlet of the spray plate, and the chamber body defines a gas source interface; and when the spray plate is in contact with the annular flange, an external gas source is able to enter the processing space through the gas source interface, the gas guide members, and the spray plate.

13. The processing chamber as claimed in claim 12, wherein a retractable spring is disposed inside each installation hole, and an end of the gas guide member is connected to the annular flange through the retractable spring; when the spray plate is in contact with the annular flange, the retractable spring allows an opposite end of the gas guide member to be pressed against the spray plate.

14. The processing chamber as claimed in claim 1, wherein the chamber body assembly comprises a gas-extracting cylinder, and the gas-extracting cylinder is connected to an end of the chamber body away from the spray plate; and a cross-section of the gas-extracting cylinder tapers in a direction away from the spray plate, and the processing gas is drawn out through the gas-extracting cylinder.

15. The processing chamber as claimed in claim 14, wherein the gas-extracting cylinder comprises an inner ring gas-extracting cylinder and an outer ring gas-extracting cylinder, and the outer ring gas-extracting cylinder is sleeved outside the inner ring gas-extracting cylinder; the inner ring gas-extracting cylinder is able to be in direct contact with the carrier, so as to extract the processing gas inside the carrier; and the outer ring gas-extracting cylinder is configured to extract the gas from a space between the carrier and the chamber body.

16. The processing chamber as claimed in claim 4, wherein the chamber body assembly comprises a heater, the heater is disposed on four surfaces of an inner side wall of the chamber body, and the heater is configured to heat the processing gas.

17. The processing chamber as claimed in claim 16, wherein the heater comprises a heating element and a heating cover, and the heating element is accommodated in the heating cover; and a surface of the heating cover is disposed on the inner side wall of the chamber body, and an opposite surface of the heating cover is corrugated.

18. The processing chamber as claimed in claim 16, wherein the heater is detachably connected to the inner side wall of the chamber body.

19. The processing chamber as claimed in claim 1, wherein the chamber body assembly comprises an insulation layer, the insulation layer surrounds the chamber body, a protective cover surrounds the insulation layer, and a grounding wire is disposed on the protective cover.

20. A substrate processing method, comprising:
providing a processing chamber, wherein the processing chamber comprises:
a chamber body assembly, comprising a chamber body; and
a chamber door assembly, comprising a spray plate and a chamber door; wherein the spray plate is disposed on the chamber door; when the chamber door assembly is closed, the spray plate is disposed on and covers an end of the chamber body; the chamber body and the spray plate define a processing space, and the spray plate is configured to introduce a processing gas into the processing space;
transferring a carrier that is configured to load a substrate into the processing chamber; and
covering the spray plate on the chamber body, and introducing the processing gas into the processing space through the spray plate to process the substrate.

21. The substrate processing method as claimed in claim 20, wherein the carrier is enclosable; and when the carrier is placed in the processing chamber, an end of the carrier is in contact with the spray plate, and an opposite end of the carrier is in contact with an inner ring gas-extracting cylinder of the processing chamber.

22. The substrate processing method as claimed in claim 21, wherein introducing the processing gas comprises introducing the processing gas into the carrier through the spray plate, a barrier gas is introduced into the processing space outside the carrier through a plurality of gas curtain holes defined in an inner side wall of the chamber body, and pressure of the barrier gas is greater than pressure of the processing gas inside the carrier.

23. The substrate processing method as claimed in claim 22, further comprising:
extracting the processing gas from inside the carrier through the inner ring gas-extracting cylinder; and
extracting the barrier gas from a space between the carrier and the chamber body through an outer ring gas-extracting cylinder.

24. A processing device, comprising:
at least two processing chambers, wherein each processing chamber comprises:
a chamber body assembly, comprising a chamber body; and
a chamber door assembly, comprising a spray plate and a chamber door; wherein the spray plate is disposed on the chamber door; when the chamber door assembly is closed, the spray plate is disposed on and covers an end of the chamber body; the chamber body and the spray plate define a processing space;
wherein the at least two processing chambers are stacked and connected in a horizontal direction or a vertical direction; and a side wall of a connection area between every two adjacent processing chambers defines an opening, so that the at least two processing chambers are communicated;
the chamber body is configured to accommodate a carrier, and the carrier is configured for loading a substrate; and a heater is disposed between the carrier and an inner side wall of the chamber body, and the heater is distributed around the chamber body; and
an end of the chamber body is provided with the spray plate, and a gas outlet part of the spray plate corresponds to a cross-section of the carrier; and the spray plate is configured to introduce a processing gas into the processing space to process the substrate.
